(19) United States
(12) Patent Application Publication
(10) Pub. No.: US 2024/0063063 A1
(43) Pub. Date: Feb. 22, 2024

(54) COMPACT CMOS FABRICATION

(71) Applicant: JAMES D. WELCH, OMAHA, NE (US)

(72) Inventor: JAMES D. WELCH, OMAHA, NE (US)

(21) Appl. No.: 17/803,985

(22) Filed: Feb. 16, 2023

Related U.S. Application Data
(63) Continuation-in-part of application No. 16/974,016, filed on Sep. 8, 2020, now Pat. No. 11,798,946.
Application No. 16/974,016 is a continuation-in-part of application No. 17/300,746, filed on Oct. 18, 2021.
Application No. 17/300,746 is a continuation-in-part of application No. 17/803,739, filed on Nov. 4, 2022.
(60) Provisional application No. 63/280,053, filed on Nov. 16, 2021.

(51) Int. Cl. H01L 21/8238; H01L 27/092; H01L 29/66; H01L 29/78

(52) U.S. Cl. CPC H01L 21/823821; H01L 21/823807; H01L 27/0924; H01L 29/66795; H01L 29/785

(57) ABSTRACT

CMOS Systems formed in a Semiconductor Substrate and involving use of material that forms a rectifying junction with both N and P-type Field Induced Semiconductor, in combination with, preferably, Parallel and Adjacent Channels subject to control by a Gate removed from said Channels by insulator.

This Application is a CIP of Pending Applications Ser. Nos. 16/974,016 Filed Sep. 8, 2020 and Ser. No. 17/300,746 Filed Oct. 18, 2021, and Ser. No. 17/803,739 Filed Nov. 4, 2021, and further Claims Benefit of Provisional Application Ser. No. 63/280,053 Filed Nov. 16, 2021.

### TECHNICAL FIELD

The present invention relates to Complementary Metal Oxide Semiconductor (CMOS) technology, and more particularly to, in a preferred embodiment, an approach to fabricating Compact CMOS System formed in a Semiconductor Substrate that comprises material which forms rectifying junctions both N and P-type Field Induced Semiconductor in combination with Parallel and Adjacent Channels, subject to control by a Gate removed from said Channels by insulator.

### BACKGROUND

CMOS systems are well established, with an improvement in recent years being FINFET geometry, which had its origin about or so years ago as demonstrated by Patent to Hu et al., U.S. Pat. No. 6,413,802 which is incorporated hereinto by reference. “FIN” is terminology given to semiconductor projections from a planar surface of a semiconductor substrate as they resemble fins on fish. The geometry of the FIN allows for application of MOS Gate Electrodes not only above a Channel of a MOSFET formed in a substrate, but also to Sides of the effective 3D Structure. There are literally thousands of FINFET references now available, but none of which Inventor Welch is aware remotely disclose the present invention.

Continuing, Inventor Welch previously Patented the use of material which forms rectifying junctions with both N and P-type Silicon, whether the effective doping type is metallurgical or field induced. See Patents U.S. Pat. Nos. 6,624,493; 5,663,584; 5,760,449; 6,091,128 and 6,268,636, (all of which are incorporated hereinto by reference). The listed Patents to Welch report work performed under a Grant from the US Dept. of Energy under Contract No. DE-FG47-93R701314, beginning in 1992. The work was performed in the 1990's and early 2000's at the University of Nebraska Electrical Engineering Dept. Another related Patent to Welch is U.S. Pat. No. 4,696,093, upon which the DOE Grant was initially based. In prior work, Inventor Welch had hands-on discovered that Chromium Disilicide was formed in Silicon by annealing Chromium (deposited via Electron beam or Sputtering onto Silicon) at about 600 degrees Centigrade, and said Chromium Disilicide forms rectifying junctions with either both N and P-type Silicon. Welch discovered, when following up on a request from his Professor (R. S. C. Cobbold), that Chromium Disilicide formed a very good rectifying with N-type Silicon during his Masters work at Toronto in the early 70's when seeking to learn if Chromium deposited on SiO₂ migrated thereinto during a 600 degree C. anneal. (See “Migration of Ion-Implanted Krypton in Silicon During Anneal”, Welch, Davies and Cobbold, J. Appl. Physics, Vol. 48, No. 11, November 1977) for discussion of migration properties of Amorphizing Krypton ions implanted into silicon at various doses and energies during anneal). That temperature was important as his DMOST-type fabrication process as that involved regrowth of an amorphized region at the surface of a substrate, into a single crystal thereby incorporating ion implanted Boron and Phosphorous dopants onto electrically active substitutional sites in a single anneal, and while the anneal was performed Chromium was present as a self-aligned atop an SiO₂ Gate Dielectric. To investigate Chromium migration in SiO₂ during anneal Welch applied Chromium to the back unpolished side of a substrate for electrical contact purposes, upon which, on the polished side thereof, was formed a MOS Capacitor. Comparing Capacitance before and after the 600 degree C. annealing resulted in the Capacitance decreasing when, if anything, an increased Capacitance was expected due to Oxide thinning caused by Chromium migration. The discovered effect was traced to the formation of a Capacitance providing rectifying junction on the rough unpolished backside of the substrate. (This was reported in his MASc. Thesis titled “Design and Fabrication of Sub-Micron Channel by Double Ion Implantation”, MASC. Dissertation, University of Toronto, 1974. See also “Fabrication of Sub-micron Channel DMOST-Type MOSFTETS by Ion-Implantation of Source, Drain and Channel”, ISAST Transactions on Computers and Intelligent Systems, No. 2, Vol. 3, 2011). Inventor Welch's MASc. hands-on research resulted in operational Sub-micron Channel length DMOST 7 type MOSFETS fabricated by ion-implantation techniques, rather than pre-deposition and drive-in diffusions. Literature searching in about 1984, soon after Inventor Welch had completed his Law Degree at the University of Nebraska and tested into the Patent and Nebraska State Bar, turned up an article by Lepselter and Sultanov titled “Some Properties of Chromium Doped Silicon”, in Soviet Physics Semiconductors”, Vol. 4, No. 11, Pages 1900-1902, May 1972 described the formation of a rectifying junction when Chromium is diffused into P-type Silicon. It was at that time Inventor Welch conceived using Chromium as a “dopant” in both N and P-type Silicon, to form a CMOS system and sought a Grant to investigate the effect. That effort eventually led to a Grant from the US Department of Energy (DOE).

A summary of the MASc. work, and the results of the work performed under the DOE Grant are presented in an unpublished proposed Ph.D. Thesis titled “Mid-Bandgap Doped Junction, Single Semiconductor Device Alternative to Conventional Dual Device CMOS, Fabrication Thereof, Operational Results, and Analysis”. Said unpublished Thesis is available from Inventor Welch at jdwscmosl@netzero.net In addition two articles “Mid-Bandgap Doped Junction, Single Semiconductor Type Device Alternative to Conventional Dual Device CMOS”, Welch, ISAST Transactions on Electronics and Signal Processing, No. 1, Vol. 4, 2010, and “Insight to Operation of a Mid-Bandgap Doped Junction Single Semiconductor Type Device Alternative to Conventional Dual Device CMOS”, Welch, ISAST Transactions On Computers and Intelligent Systems, No. 1, Vol. 3, 2010), are also identified which report the same work.

Recently Inventor Welch studied FINFET systems, and in view thereof has conceived a simple approach to fabricating a compact FINFET CMOS System, which is disclosed herein. There remains need for CMOS systems that enable higher packing density of devices, and therefore prolong the validity of Moore's Law.

Need remains for new approaches to producing Semiconductor Devices.

### DISCLOSURE OF THE INVENTION

The Present invention involves a CMOS structure comprising a region of material in a semiconductor substrate which material forms rectifying junctions with both field induced N and P-type semiconductor regions.

More specifically the Present Invention comprises a Method of Fabricating a Compact CMOS Structure which comprises a region of material in a semiconductor substrate which forms rectifying junctions with both field induced N and P-type semiconductor. Said CMOS structure further comprises at least two channels projecting from electrical contact with said region of material in a semiconductor substrate which forms rectifying junctions with both field induced N and P-type semiconductor, wherein said CMOS structure further comprises a gate structure offset with respect to said channels by insulating material. Said CMOS structure further comprises substantially non-rectifying junctions to said material which forms rectifying junctions with both field induced N and P-type semiconductor, and to distal ends of said at least two channels.

Said semiconductor substrate, at least in the regions of said channels can be characterized by a selection from the group consisting of:
it is substantially or per se. intrinsic;
it is substantially or per se. metallurigically compensated;
it contains both metallurgical N and P-type dopants in unequal concentrations;
it is metallurgically doped to provide at least one area of P-type material and at least one separate area of N-type material in each channel region.

A more specific Present Invention Compact CMOS structure comprises a region of material in a semiconductor substrate which forms rectifying junctions with both field induced N and P-type semiconductor. Said compact CMOS structure further comprising at least two channels projecting from electrical contact with said region of material in a semiconductor substrate which forms rectifying junctions with both field induced N and P-type semiconductor. Importantly in this preferred embodiment, is that said channels are substantially parallel and adjacent to one another to provide a very compact result. Again, said compact CMOS structure further comprising a gate structure offset with respect to said channels by insulating material, and said compact CMOS structure further comprises substantially non-rectifying junctions to said material which forms rectifying junctions with both field induced N and P-type semiconductor, and to distal ends of said at least two channels.

Again, said semiconductor substrate, at least in the regions of said channels can be characterized by a selection from the group consisting of:
it is substantially or per se. intrinsic;
it is substantially or per se. metallurigically compensated;
it contains both metallurgical N and P-type dopants in unequal concentrations;
it is metallurgically doped to provide at least one area of P-type material and at least one separate area.

It is noted that in all embodiments the channels can be present in FINS which project from a surface of said semiconductor substrate.

In use a voltage is applied between the substantially non-rectifying junctions at the distal ends of said at least two channels and a voltage is applied to said gate which, when switched between the voltages applied to the substantially non-rectifying distal ends of said at least two channels, causes a voltage to appear at the substantially non-rectifying junction to said region of material which forms rectifying junctions with both field induced N and P-type semiconductor which is inverted, in that when the higher of said voltages applied to the substantially non-rectifying junctions to said distal ends of said at least two channels is applied to said gate, the voltage at the substantially non-rectifying junction to said region of material which forms rectifying junctions with both field induced N and P-type semiconductor is low, and vice-versa.

The Present Invention is more directly a compact CMOS structure formed in a semiconductor substrate by:
a) selecting a semiconductor substrate, identifying insulating material, and identifying material that forms rectifying junctions with both N and P-type field induced doping in said selected semiconductor substrate when present in said semiconductor substrate;
b) configuring said semiconductor substrate, said insulating material and said material that forms rectifying junctions with both N and P-type field induced doping when said material is present in said semiconductor substrate, to comprise said compact CMOS structure;
said compact CMOS structure being characterized by two channels projecting from electrical contact with said region of material that forms rectifying junctions with both N and P-type field induced doping in said semiconductor substrate, wherein said channels are substantially parallel and adjacent to one another;
said compact CMOS structure further comprising a gate structure offset with respect to said channels by said insulating material; and said compact CMOS structure further comprising substantially non-rectifying junctions to said material which forms rectifying junctions with both field induced N and P-type semiconductor, and to distal ends of said two channels;
such that in use a voltage is applied between the substantially non-rectifying junctions at the distal ends of said two channels and a voltage is applied to said gate which, when switched between the voltages applied to the substantially non-rectifying distal ends of said two channels, causes a voltage to appear at the substantially non-rectifying junction to said region of material which forms rectifying junctions with both field induced N and P-type semiconductor which is inverted, in that when the higher of said voltages applied to the substantially non-rectifying junctions to said distal ends of said two channels is applied to said gate, the voltage at the substantially non-rectifying junction to said region of material which forms rectifying junctions with both field induced N and P-type semiconductor is low, and vice-versa.

Said compact CMOS structure can comprise that the semiconductor substrate, at least in the regions of said channels, is characterized by a selection from the group consisting of:
it is substantially or per se. intrinsic;
it is substantially or per se. metallurgically compensated;
it contains both metallurgical N and P-type dopants in unequal concentrations;
it is metallurgically doped to provide at least one area of P-type material and at least one separate area of N-type material in each channel region.

Said compact CMOS structure can provide that said channels are present in FINS which project from surface of said semiconductor substrate.

The Present Invention is further a Method of fabricating compact CMOS structure formed in a semiconductor substrate comprising:
a) selecting a semiconductor substrate, identifying insulating material, and identifying material that forms rectifying junctions with both N and P-type field induced doping in Said selected semiconductor substrate when present in said semiconductor substrate;
b) configuring said semiconductor substrate, said insulating material and said material that forms rectifying junctions with both N and P-type field induced doping when said material is present in said semiconductor substrate, to comprise said compact CMOS structure;
said compact CMOS structure being characterized by two channels projecting from electrical contact with said region of material that forms rectifying junctions with both N and P-type field induced doping in said semiconductor substrate, wherein said channels are substantially parallel and adjacent to one another;
said compact CMOS structure further comprising a gate structure offset with respect to said channels by said insulating material; and said compact CMOS structure further comprising substantially non-rectifying junctions to said material which forms rectifying junctions with both field induced N and P-type semiconductor, and to distal ends of said two channels;
such that in use a voltage is applied between the substantially non-rectifying junctions at the distal ends of said two channels and a voltage is applied to said gate which, when switched between the voltages applied to the substantially non-rectifying distal ends of said two channels, causes a voltage to appear at the substantially non-rectifying junction to said region of material which forms rectifying junctions with both field induced N and P-type semiconductor which is inverted, in that when the higher of said voltages applied to the substantially non-rectifying junctions to said distal ends of said two channels is applied to said gate, the voltage at the substantially non-rectifying junction to said region of material which forms rectifying junctions with both field induced N and P-type semiconductor is low, and vice-versa.

It is to be appreciated that a critical step in the Product by Process, or Method herein is, after selecting a Semiconductor Substrate, identifying material that forms rectifying junctions with both N and P-type field induced doping in said selected semiconductor substrate when present in said semiconductor substrate. Different Semiconductors require different materials. This step can be practiced by causing a region of material to be present in both metallurgically doped N and P-type semiconductor and testing the rectifying properties of both. For insight it is noted that Inventor Welch stumbled on that fact that Chromium Annealed to N-type Silicon formed a very good rectifying junction during his MASc. hands-on work in the early 70's. In the 80's he found an article which taught that Chromium diffused into P-type Silicon formed a rectifying junction. This was simply luck and not the result of practicing a defined method. A Religious sort might even say it was a gift from God. It was at the point arrived at by luck, however, that Inventor Welch, under a DOE Grant to investigate the phenomena, fabricated junctions on both N and P-type Silicon by depositing Chromium thereonto and annealing the substrates at 600 Degrees Centigrade for 30 minutes which formed Chromium-Disilicide where the Chromium as in contact with the Silicon. This approach established that Chromium was a suitable material for application in a present Invention fabrication procedure where Silicon is selected as the Semicondtictor. While not directly tested, there is reason to believe that Vanadium might also be a suitable material where either Silicon (Si) or Silicon Carbide (SiC) is selected as the Semiconductor. (Note, it had been intended to try Vanadium under the DOE Grant, but equipment problems consumed time and prevented that effort). The general reason for this is that Vanadium forms a near Mid-Bandgap Dopant State in those Semiconductors, as did Chromium in Silicon. Fabrication of a Present Invention Compact CMOS Structure in a selected Semiconductor will always require a step of determining the properties of junctions between a selected material and a selected Semiconductor. Said Step would perhaps have to be practiced only once, and once a material is identified as suitable for use in a specific Semiconductor, selection would be based on knowledge. This is much like the situation existing when one first solves a Math problem. One much work through it carefully and methodically, but once solved, knowing the answer is a matter of recollection. But in some form the step would have to be practiced before any large scale device fabrication would be feasible. Formulation of the Material identification for a selected semiconductor Method Step, is original with this Application.

In addition the identification of appropriate Insulator Material for use with Gate structures must be performed. When Silicon is selected as a Substrate, it is likely thermally grown SiO₂ will be the Insulator, but not necessarily. Insulator can also be deposited. It also is noted that material that forms rectifying junctions with both N and P-type field induced doping in said selected semiconductor substrate can be deposited thereonto, ion-implanted thereinto etc. and the result be subjected to annealing.

The semiconductor substrate can perhaps be selected to be any semiconductor. For instance any Group IV semiconductors, or Group IV Compound Semiconductors or Group VI Elemental Semiconductors such as, or III-V Semiconductors such as, or II-VI Semiconductors, or I-VII Semiconductors, or IV-VI Semiconductors, or V-VI Semiconductors, or II-V Semiconductors, or I-III-VI₂ Semiconductors, or Oxide Semiconductors, or Layered or Magnetic or Organic or Charge-transfer complexes etc. Specific examples of Semiconductors are: C, Si, Ge, Sn, SiC, S₈, Sₑ, Te, BN, BP, BAs, B₁₂As₂, AIN, AIP, AlAs, AlSb, GaN, GaP, GaAs, GaSb, InP, InAs, InSb, CdSe, CdS, CdTe, ZnO, ZnSe, ZnS, ZnTb, CuCl, Cu₂S, PbSe, PbTe, SnS, SnS₂, SnTe, Pb₁₋ₓSnₓTe, Bi₂Te₃, Cd₃P₂, Cd₃As₂, Zn₃P₂, ZnP₂, Zn₃P₂, ZnP₂, Zn₃P₂, ZnP₂, Zn₃AS₂, Zn₃Sb₂, TiO₂, Cu₂O, CuO, UO₂, SnO₂, BaTiO₃, SrTiO₃, LiNbO₃, VO₂, PbI₂, MoS₂, GaSe, InSe, SnS, Bi₂S₃, GaMnAs, InMnAs, CdMnTe, PbMnTe, La_{0.7}Ca_{0.3}MnO₃, FeO, NiO, EuO, EuS, CrBr₃, CuInSe₂, AgGaS₂, ZnSiP₂, Ag₂S₃, As₄S₄, PtSi, BiI₃, HgI₂, TiBr, Ag₂S, FeS₂, Cu₂ZnSnS₄, Cu_{1.18}Zn_{0.4}Sb_{1.90}S_{7.2}, Cu₂Sn₃, Pb₁₋ₓSnₓTe, Si₁₋ₓGex, Si₁₋ₓSnx, Alₓ Ga₁₋ₓAs, InₓGa₁₋ₓAS, IbₓGa₁₋ₓ, AlₓIn₁₋ₓSb, GaAsN, GaAsP, GaAsSb, AlGaN, AlGaP, InGaN, InAsSb, InGaSb.AlGaInP, AlGaAsP, InGaAsSb, InAsSbP, AlInAsP, AlInAsN, GaAsSbN, GaInNAsSb, GaInAsSbP, CdZnTe, HgCdTe, HgZnTe, HgZnSe, (Zn₁₋ₓCd)₃(P_{1-y}AsY)₂, Cu(In, Ga)Se₂.

In more detail, the present invention system can be fabricated by a relatively simple method. Said method comprising the steps of:
a) selecting a semiconductor substrate having at least one polished side;
b) depositing or growing insulator on at least one polished surface thereof;
c) etching openings through insulator regions where material that forms rectifying junctions with both N and P-type semiconductor is to be present;
d) depositing or ion-implanting material that forms rectifying junctions with both N and P-type semiconductor;
e) annealing or otherwise causing the deposited material that forms rectifying junctions with both N and P-type semiconductor to form rectifying junctions with the semiconductor in the regions opened in step c);
f) removing unreacted material that forms rectifying junctions with both N and P-type semiconductor in all areas other than in the regions opened in step c);
g) opening areas in the insulator where ohmic contact to ends of channel regions are to be present;
h) depositing a material suitable for use as a gate over the entire substrate;
i) delineating the system such that said metal provides a gate over two channels in the semiconductor, said two channels projecting from the region of material that forms rectifying junctions with both N and P-type semiconductor, and ending at separate ohmic contact region; while also delineating ohmic contacts with regions of said material that forms rectifying junctions with both N and P-type semiconductor;
j) sintering said delineated system to form ohmic contacts at the ends of channels and with the regions of material that forms rectifying junctions with both N and P-type semiconductor

As a non-limiting example, said method can provide that the substrate is silicon, the material that forms rectifying junctions with both N and P-type semiconductor in step e) is chromium which is annealed to produce chromium-disilisde by reaction with said silicon, and the metal deposited in step h) is aluminum. Additional steps can be incorporated to provide different gate threshold voltage adjusting materials are present, and/or to provide wall on sides of a gate etc.

Said method can comprise an additional step conducted between steps a) and b), said additional step a′) comprising conducting a semiconductor etch that form a multiplicity of substantially parallel adjacent pairs of FINS, each of which projects from the polished surface of said substrate and the method is one of fabricating compact FINFET CMOS systems.

Note, in step b) it might be necessary to grow or deposit a fairly thick (eg. up to Microns) insulating layer and then in a step b′) thin it in the channel regions. This could involve removing all insulator in the eventual channel regions and again growing or depositing a thinner layer of insulator appropriate for use as a Gate insulator (eg. far less than 1000 Angstroms). In particular, FIG. 2 of the Drawing should be viewed as a non-limiting example only. The important thing to take from FIG. 2 is that the Gate (G) affects both Channels (F1) (F2) similarly at once, as they are in close proximity. In conventional CMOS the N and P Channel devices the two Gates involved and are electrically accessed separately. Further, it is to be appreciated that the “channels” referred to are simply regions in a substrate which become affected by a carrier attracting or repelling voltage applied to the gate. When the channel regions constitute FINS however, they are, of course, more easily defined by observable device geometry. Further, the language “substantially parallel”, of course, includes the case where the channel regions are in fact actually parallel.

The Present Invention will be better understood by reference to the Detailed Description Section of the Specification, in conjunctions with the Drawings.

### BRIEF DESCRIPTION OF THE DRAWINGS

FIG. 1 shows a perspective view of a prior art FINFET.

FIG. 2 shows a perspective view of a present invention Compact FINFET CMOS system.

FIG. 3 is shows a front elevational view of the FIG. 2 system, showing the Insulator (I) between the Gate (G) and FIN (F2).

FIGS. 4 and 5 are adapted from Patent to Welch, U.S. Pat. No. 6,624,493 and serve to indicate the Inverting Nature of the present invention.

### DETAILED DESCRIPTION

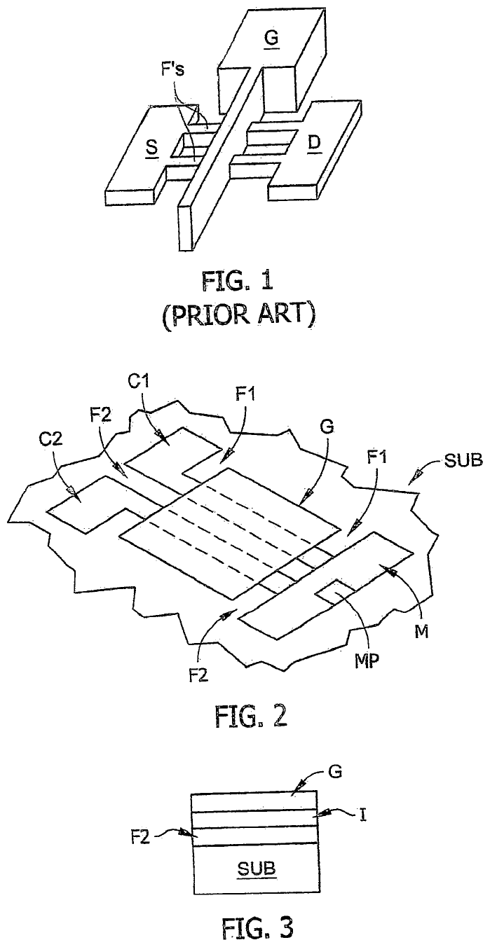

FIG. 1 shows a perspective view of a prior art early depiction of a FINFET, adapted from U.S. Pat. No. 6,413,802. This Figure is provided as it provides insight as to how inventor Welch herein conceived the present invention. Basically, replacing the Drain (D) with a Material that forms rectifying junctions with both N and P-type material, results in the present invention structure.

FIG. 2 shows a perspective view of a present invention Compact CMOS system in a planar substrate. Note the presence of a region of material (M) in a semiconductor substrate (SUB) which forms rectifying junctions with both field induced N and P-type semiconductor. The compact CMOS structure further comprises at least two Channels, (eg. indicated as FINS (F1) (F2)) projecting from electrical contact with said region of material in a semiconductor substrate which forms rectifying junctions with both field induced N and P-type semiconductor (M), said FINS (F1) (F2) being substantially parallel and adjacent to one another to make the system as compact as possible. Said compact CMOS structure further comprises a gate (G) structure offset with respect to said FINS (F1) (F2) by insulating material (I) as shown better in FIG. 3. The compact CMOS structure further comprises substantially non-rectifying junctions (C1), (C2) and (MP) to said distal ends of said at least two FINS material (F1) (F2) and to the Material (M), respectively. It is to be understood that a region out from under the Gate that provides indication of FINS (F1) and (F2) FIG. 2 is not meant to imply that any distance must be present in a fabricated system, but is there only to allow indication (F1) and (F2). In a preferred embodiment there is little such gap between the left and right side of the Gate (G) and the substantially non-rectifying junctions (C1) (C2) and (M).

It is noted that while FIG. 2 in particular shows Gate (G) Material over a relatively large area, it must be present only over Channel Regions (F1) and (F2). To reduce Gate Capacitance a significant area of Gate (G) Material can be removed leaving only Electrical Connected Material over Channel Regions. Is to be interpreted consistent with this.

FIG. 3 is included to as a front elevational view of the FIG. 2 system, showing the Insulator (I) between the Gate (G) and FIN (F2). Note that the Gate (G) can be a metal or a composite of metal and non-metal components. Further, the Insulator under the Gate (G) can be much thinner than at other locations, and/or the Gate (G) can be of a nature that is present only above a Channel Region (F1) (F2), as FIG. 2 can be interpreted to show, or it can be present on one of both sides and above a FIN Channel region in a semiconductor substrate, as shown in FIG. 1. The later point is not a determining factor as regards Patentability. That, it is believed is found in the unique combination teachings regarding application of material in a semiconductor substrate which forms rectifying junctions with both field induced N and P-type semiconductor in the identified Patents by Welch, which teaching have not previously been applied to systems comprising parallel adjacent FINS or channels (F1) (F2), and in the many FINFET related Patents, such as U.S. Pat. No. 6,413,802 to Hu et al. Inventor Welch has combined elements, each arguably present in various prior art publications, in a novel way he was positioned to appreciate resulting from a chance discovery in his Masters work that Chromium annealed to N-type Silicon formed a very good rectifying junction, in combination with discovery of the previously mentioned Lepselter and Sultanov article which reported Chromium did likewise with P-type Silicon, all in combination with recently developed insight to the FINFET structure which naturally lends itself to providing substantially parallel and adjacent Channel regions (F1) (F2) which can both be conveniently subject to a single Gate (G) voltage in use. MOSFET structures that are formed from sequential N and P-Channel devices in N and P doped regions on a substrate must use a split gate as did the results Welch reported in his previous Patents. The present invention, again, does not require space consuming alternating N and P-type regions in a substrate, but rather uses only a substantially Intrinsic or at least partially or substantially completely Compensated substrate, in the region of substantially parallel and adjacent channels, to achieve a Compact CMOS system.

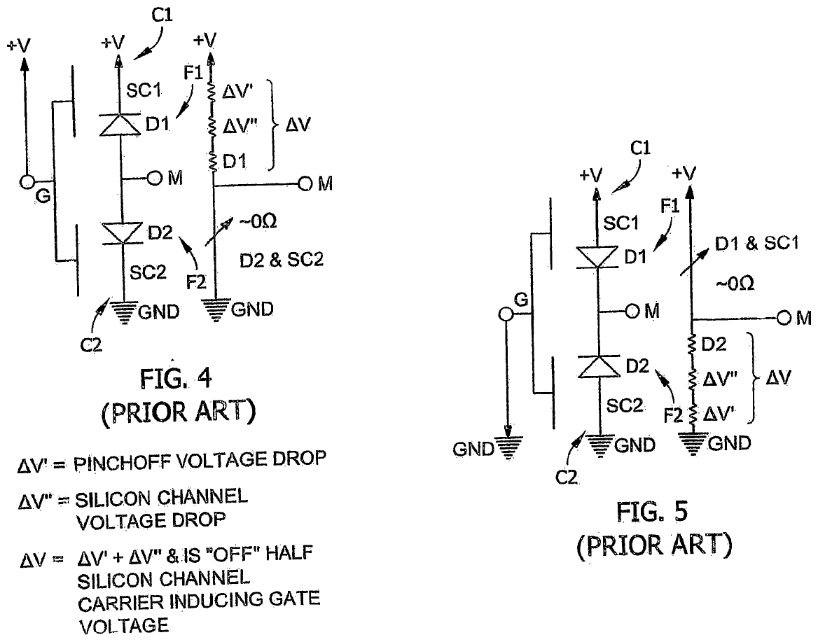

FIGS. 4 and 5 are adapted from Patent to Welch, U.S. Pat. No. 6,624,493, amongst other publications by Welch, and serve to indicate the Inverting Nature of the present invention. Said FIGS. show an exemplary biasing situation wherein a Positive Voltage is applied to (C1), and (C2) is Grounded. The Ground could just as well be a Negative Voltage and therefore FIGS. 4 and 5 are not limiting. Note that when the Gate (G) Voltage is at +V in FIG. 4, the Midpoint (MP) of the present Compact FINFET CMOS system is at Ground (GND). FIG. 5 shows that when the Gate (G) Voltage is at Ground (GND), the Midpoint (MP) of the present Compact FINFET CMOS system is at +V, thus Inversion occurs. As perhaps better described in the previously mentioned unpublished Thesis by Welch, it should be appreciated that the same Gate voltage is applied to Gates (G) in both Channel Regions (F1) and (F2). When the Gate Voltage is High at +V, electrons are attracted into both Cannels (F1) and (F2); which makes the Lower junction D2 Forward Biased, and when Gate Voltage is Low at Ground (or a negative value) Holes are pulled into both Channel Regions (F1) and (F2) the Upper junction (D1) is Forward-biased. In the First Case the voltage appearing at the Midpoint (MP) is Low and in the Second Cases the midpoint (MP) Voltage is high, thus Inversion is accomplished. It is also noted that an Off Side will present barriers to Conduction as a result of at least two sources. First a Channel Pinchoff Voltage (AV′), and Second a Channel Resistance (AV″) will be present.

It is noted that in Inventor Welch's earlier Single Device CMOS fabrication work under the previously mentioned DOE Grant, the two device channels (equivalent to the two FINS (F1) and (F2) were sequential, hence the Gate was split and the resulting S-CMOS devices were not very compact, much as is the case with conventional P-N Junction based CMOS systems. In the present Compact FINFET CMOS system however, the substantially parallel and adjacent FINS (Channels) (F1) and (F2) are present adjacent to one another, and operated from a single Gate (G) structure. This is why the present FINFET system is compact. The present Device Configuration is not, to Inventor Welch's knowledge, remotely suggested in any prior art. It was only because of Inventor Welch's prior experience that the Present. Invention conceived. Note as well that no N and P-type wells are necessary to fabricate P and N Channel MOSFETS as now Claimed. Inventor Welch did his earlier DOE sponsored fabrication of Single Device CMOS on Intrinsic Silicon, (see his Patents U.S. Pat. Nos. 6,624,493; 5,663,584; 5,760,449; 6,091,128 and 6,286,636) and the previously mentioned Unpublished Thesis, but it is thought that use of Compensated Semiconductor might provide benefit, though there was not time to try that prior work. This lack of the need for space consuming N and P-doped wells is another factor that enables the present system to be compact, and makes the present invention less energy intensive to realize. For emphasis, the major factor enabling the present invention is that some materials (M) form rectifying junctions with either N or P-type filed induced effective doping n a Channel region of a MOSFET. FIGS. 4 and 5 demonstrate the benefit that provides. A further consideration is that P-N junctions involve space-charge regions which limit how small a channel can be without punch-through occurring. This is not a problem where the junctions are hot carrier type as in the present invention. It is believed Patentability attaches to the Present Invention as it overcomes many problems associated with previously known CMOS structures, while importantly, providing a very compact system via placement of channels adjacent to one another both of which are influenced by a single Gate (G).

It is noted that “substantially non-rectifying” and “Substantially ohmic” are to be read as equivalent herein.

The present invention in FIG. 2 can be viewed as a prior art FIG. 1 system in which the Drain (D) is replaced with a region of material (M) that formsrectifying junctions with both field induced N and P-type semiconductor, and the Gate (G) is expanded to cover more of the FIG. 1 FIN Channels (F's). Nothing in Hu et al. 802 or any other known reference remotely suggests that. Further nothing in Hu et al. 802 remotely suggests that one skilled in the art of FINFET systems should seek out material that forms rectifying junctions with both field induced N and P-type semiconductor. It is only because of Inventor Welch's experience and insight in the area that he conceived the present invention. Further, Inventor Welch has found that his idea of using material that forms rectifying junctions with both field induced N and P-type semiconductor seems not to have been generally appreciated by people involved in solid state device design. A Professor at Illinois University for instance, when asked by the Government to evaluate his work based on his first Patent in the area using Silicon as the Semiconductor—thoroughly trashed it. When Inventor Welch phoned that Professor and walked him through it, he commented that he had completely missed the invention—and that Welch had performed Ph.D. level research. No further funding developed, however.

Having hereby disclosed the subject matter of the present invention, it should be obvious that many modifications, substitutions and variations of the present invention are possible in view of the teachings. It is therefore to be understood that the invention may be practiced other than as specifically described, and should be limited only in its breadth and scope only by the Claims.

I claim:

1. A compact CMOS structure formed in a semiconductor substrate by a method comprising:
a) selecting a semiconductor substrate, identifying insulating material, and identifying material that forms rectifying junctions with both N and P-type field induced doping in said selected semiconductor substrate when present in said semiconductor substrate;
b) configuring said semiconductor substrate, said insulating material and said material that forms rectifying junctions with both N and P-type field induced doping when said material is present in said semiconductor substrate, to comprise said compact CMOS structure;
said compact CMOS structure being characterized by two channels projecting from electrical contact with said region of material that forms rectifying junctions with both N and P-type field induced doping in said semiconductor substrate, wherein said channels are substantially parallel and adjacent to one another;
said compact CMOS structure further comprising a gate structure offset with respect to said channels by said insulating material; and
said compact CMOS structure further comprising substantially non-rectifying junctions to said material which forms rectifying junctions with both field induced N and P-type semiconductor, and to distal ends of said two channels;
such that in use a voltage is applied between the substantially non-rectifying junctions at the distal ends of said two channels and a voltage is applied to said gate which, when switched between the voltages applied to the substantially non-rectifying distal ends of said two channels, causes a voltage to appear at the substantially non-rectifying junction to said region of material which forms rectifying junctions with both field induced N and P-type semiconductor which is inverted, in that when the higher of said voltages applied to the substantially non-rectifying junctions to said distal ends of said two channels is applied to said gate, the voltage at the substantially non-rectifying junction to said region of material which forms rectifying junctions with both field induced N and P-type semiconductor is low, and vice-versa.

2. A compact CMOS structure as in claim 1, in which the step of identifying material that forms rectifying junctions with both N and P-type field induced doping in said selected semiconductor substrate when present in said semiconductor substrate comprises, at least once, causing a region of material to be present in both metallurgically doped N and P-type semiconductor and testing the rectifying properties of the junctions in both substrates.

3. A compact CMOS structure as in claim 2, in which selection of an appropriate material us guided by identifying a material comprising at least a component thereof which provides an Energy State at approximately mid-bandgap of the selected semiconductor.

4. A compact CMOS structure as in claim 1, in which the semiconductor substrate, at least in the regions of said channels, is characterized by a selection from the group consisting of:
it is substantially or per se. intrinsic;
it is substantially or per se. metallurgically compensated;
it contains both metallurgical N and P-type dopants in unequal concentrations;
it is metallurgically doped to provide at least one area of P-type material and at least one separate area of N-type material in each channel region.

5. A compact CMOS structure as in claim 1, in which said channels are present in FINS which project from surface of said semiconductor substrate.

6. A method of fabricating a compact CMOS structure formed in a semiconductor substrate comprising:
a) selecting a semiconductor substrate, identifying insulating material, and identifying material that forms rectifying junctions with both N and P-type field induced doping in said selected semiconductor substrate when present in said semiconductor substrate;
b) configuring said semiconductor substrate, said insulating material and said material that forms rectifying junctions with both N and P-type field induced doping when said material is present in said semiconductor substrate, to comprise said compact CMOS structure;
said compact CMOS structure being characterized by two channels projecting from electrical contact with said region of material that forms rectifying junctions with both N and P-type field induced doping in said semiconductor substrate, wherein said channels are substantially parallel and adjacent to one another;
said compact CMOS structure further comprising a gate structure offset with respect to said channels by said insulating material; and
said compact CMOS structure further comprising substantially non-rectifying junctions to said material which forms rectifying junctions with both field induced N and P-type semiconductor, and to distal ends of said two channels;
such that in use a voltage is applied between the substantially non-rectifying junctions at the distal ends of said two channels and a voltage is applied to said gate which, when switched between the voltages applied to the substantially non-rectifying distal ends of said two channels, causes a voltage to appear at the substantially non-rectifying junction to said region of material which forms rectifying junctions with both field induced N and P-type semiconductor which is inverted, in that when the higher of said voltages applied to the substantially non-rectifying junctions to said distal ends of said two channels is applied to said gate, the voltage at the substantially non-rectifying junction to said region of material which forms rectifying junctions with both field induced N and P-type semiconductor is low, and vice-versa.

7. A method as in claim 6, in which the step of identifying material that forms rectifying junctions with both N and P-type field induced doping in said selected semiconductor substrate when present in said semiconductor substrate comprises, at least once, causing a region of material to be present in both metallurgically doped N and P-type semiconductor and testing the rectifying properties of the junctions in both substrates.

8. A compact CMOS structure as in claim 7, in which selection of an appropriate material us guided by identifying a material comprising at least a component thereof which provides an Energy State at approximately mid-bandgap of the selected semiconductor.

9. A compact CMOS structure as in claim 6, in which the semiconductor substrate, at least in the regions of said channels, is characterized by a selection from the group consisting of:
it is substantially or per se. intrinsic;
it is substantially or per se. metallurgically compensated;
it contains both metallurgical N and P-type dopants in unequal concentrations;
it is metallurgically doped to provide at least one area of P-type material and at least one separate area of N-type material in each channel region.

10. A compact CMOS structure as in claim 6, in which said channels are present in FINS which project from surface of said semiconductor substrate.

11. A compact CMOS structure formed in a semiconductor substrate by a method comprising:
a) selecting a semiconductor substrate, identifying insulating material, and identifying material that forms rectifying junctions with both N and P-type field induced doping in said selected semiconductor substrate when present in said semiconductor substrate;
b) configuring said semiconductor substrate, said insulating material and said material that forms rectifying junctions with both N and P-type field induced doping when said material is present in said semiconductor substrate, to comprise said compact CMOS structure;
said compact CMOS structure being characterized by two channels projecting from electrical contact with said region of material that forms rectifying junctions with both N and P-type field induced doping in said semiconductor substrate, said compact CMOS structure further comprising a gate structure offset with respect to said channels by said insulating material; and
said compact CMOS structure further comprising substantially non-rectifying junctions to said material which forms rectifying junctions with both field induced N and P-type semiconductor, and to distal ends of said two channels;
such that in use a voltage is applied between the substantially non-rectifying junctions at the distal ends of said two channels and a voltage is applied to said gate which, when switched between the voltages applied to the substantially non-rectifying distal ends of said two channels, causes a voltage to appear at the substantially non-rectifying junction to said region of material which forms rectifying junctions with both field induced N and P-type semiconductor which is inverted, in that when the higher of said voltages applied to the substantially non-rectifying junctions to said distal ends of said two channels is applied to said gate, the voltage at the substantially non-rectifying junction to said region of material which forms rectifying junctions with both field induced N and P-type semiconductor is low, and vice-versa.

12. A compact CMOS structure as in claim 11, in which the step of identifying material that forms rectifying junctions with both N and P-type field induced doping in said selected semiconductor substrate when present in said semiconductor substrate comprises, at least once, causing a region of material to be present in both metallurgically doped N and P-type semiconductor and testing the rectifying properties of the junctions in both substrates.

13. A compact CMOS structure as in claim 12, in which selection of an appropriate material us guided by identifying a material comprising at least a component thereof which provides an Energy State at approximately mid-bandgap of the selected semiconductor.

14. A compact CMOS structure as in claim 11, in which the semiconductor substrate, at least in the regions of said channels, is characterized by a selection from the group consisting of:
it is substantially or per se. intrinsic;
it is substantially or per se. metallurgically compensated;
it contains both metallurgical N and P-type dopants in unequal concentrations;
it is metallurgically doped to provide at least one area of P-type material and at least one separate area of N-type material in each channel region.

15. A compact CMOS structure as in claim 12, in which said channels are present in FINS which project from surface of said semiconductor substrate.

16. A compact CMOS structure as in claim 1, in which the semiconductor substrate is selected from the group consisting of:
C, Si, Ge, Sn, SiC, S₈, Sₑ, Te, BN, BP, BAs, B₁₂As₂, AIN, AIP, AlAs, AlSb, GaN, GaP, GaAs, GaSb, InP, InAs, InSb, CdSe, CdS, CdTe, ZnO, ZnSe, ZnS, ZnTb, CuCl, Cu₂S, PbSe, PbTe, SnS, SnS₂, SnTe, Pb₁₋ₓSnₓTe, Bi₂Te₃, Cd₃P₂, Cd₃As₂, Zn₃P₂, ZnP₂, Zn₃P₂, ZnP₂, Zn₃P₂, ZnP₂, Zn₃As₂, Zn₃Sb₂, TiO₂, Cu₂O, CuO, UO₂, SnO₂, BaTiO₃, SrTiO₃, LiNbO₃, VO₂, PbI₂, MoS₂, GaSe, InSe, SnS, Bi₂S₃, GaMnAs, InMnAs, CdMnTe, PbMnTe, La_{0.7}Ca_{0.3}MnO₃, FeO, NiO, EuO, EuS, CrBr₃, CuInSe₂, AgGaS₂, ZnSiP₂, Ag₂S₃, As₄S₄, PtSi, BiI₃, HgI₂, TiBr, Ag₂S, FeS₂, Cu₂ZnSnS₄, Cu_{1.18}Zn_{0.4}Sb_{1.90}S_{7.2} Cu₂Sn₃ r Pb₁₋ₓSn₁₋ₓTe, Si₁₋ₓGex, Si₁₋ₓSnX AlₓGa₁₋ₓAs, InₓGa₁₋ₓAs, IbₓGa₁₋ₓ, AlₓIn₁₋ₓSb, GaAsN, GaAsP, GaAsSb, AlGaN, AlGaP, InGaN, InAsSb, InGaSb.AlGaInP, AlGaAsP, InGaAsSb, InAsSbP, AlInAsP, AlInAsN, GaAsSbN, GaInNAsSb, GaInAsSbP, CdZnTe, HgCdTe, HgZnTe, HgZnSe, (Zn₁₋ₓCd)₃(P_{1-y}AsY)₂ and Cu(In, Ga)Se₂.

17. A method as in claim 6, in which the semiconductor substrate is selected from the group consisting of:
C, Si, Ge, Sn, SiC, S₈, Sₑ, Te, BN, BP, BAs, B₁₂As₂, AIN, AIP, AlAs, AlSb, GaN, GaP, GaAs, GaSb, InP, InAs, InSb, CdSe, CdS, CdTe, ZnO, ZnSe, ZnS, ZnTb, CuCl, Cu₂S, PbSe, PbTe, SnS, SnS₂, SnTe, Pb₁₋ₓSnₓTe, Bi₂Te₃, Cd₃P₂, Cd₃As₂, Zn₃P₂, ZnP₂, Zn₃P₂, ZnP₂, Zn₃P₂, ZnP₂, Zn₃As₂, Zn₃Sb₂, TiO₂, Cu₂O, CuO, UO₂, SnO₂, BaTiO₃, SrTiO₃, LiNbO₃, VO₂, PbI₂, MoS₂, GaSe, InSe, SnS, Bi₂S₃, GaMnAs, InMnAs, CdMnTe, PbMnTe, La_{0.7}Ca_{0.3}MnO₃, FeO, NiO, EuO, EuS, CrBr₃, CuInSe₂, AgGaS₂, ZnSiP₂, Ag₂S₃, As₄S₄, PtSi, BiI₃, HgI₂, TiBr, Ag₂S, FeS₂, Cu₂ZnSnS₄, Cu_{1.18}Zn_{0.4}Sb_{1.90}S_{7.2} Cu₂Sn₃ r Pb₁₋ₓSn₁₋ₓTe, Si₁₋ₓGex, Si₁₋ₓSnX AlₓGa₁₋ₓAs, InₓGa₁₋ₓAs, IbₓGa₁₋ₓ, AlₓIn₁₋ₓSb, GaAsN, GaAsP, GaAsSb, AlGaN, AlGaP, InGaN, InAsSb, InGaSb.AlGaInP, AlGaAsP, InGaAsSb, InAsSbP, AlInAsP, AlInAsN, GaAsSbN, GaInNAsSb, GaInAsSbP, CdZnTe, HgCdTe, HgZnTe, HgZnSe, (Zn₁₋ₓCd)₃(P_{1-y}AsY)₂ and Cu(In, Ga)Se₂.

18. A compact CMOS structure as in claim 11, in which the semiconductor substrate is selected from the group consisting of:
C, Si, Ge, Sn, SiC, S₈, Sₑ, Te, BN, BP, BAs, B₁₂As₂, AIN, AIP, AlAs, AlSb, GaN, GaP, GaAs, GaSb, InP, InAs, InSb, CdSe, CdS, CdTe, ZnO, ZnSe, ZnS, ZnTb, CuCl, Cu₂S, PbSe, PbTe, SnS, SnS₂, SnTe, Pb₁₋ₓSnₓTe, Bi₂Te₃, Cd₃P₂, Cd₃As₂, Zn₃P₂, ZnP₂, Zn₃P₂, ZnP₂, Zn₃P₂, ZnP₂, Zn₃As₂, Zn₃Sb₂, TiO₂, Cu₂O, CuO, UO₂, SnO₂, BaTiO₃, SrTiO₃, LiNbO₃, VO₂, PbI₂, MoS₂, GaSe, InSe, SnS, Bi₂S₃, GaMnAs, InMnAs, CdMnTe, PbMnTe, La_{0.7}Ca_{0.3}MnO₃, FeO, NiO, EuO, EuS, CrBr₃, CuInSe₂, AgGaS₂, ZnSiP₂, Ag₂S₃, As₄S₄, PtSi, BiI₃, HgI₂, TiBr, Ag₂S, FeS₂, Cu₂ZnSnS₄, Cu_{1.18}Zn_{0.4}Sb_{1.90}S_{7.2} Cu₂Sn₃ r Pb₁₋ₓSn₁₋ₓTe, Si₁₋ₓGex, Si₁₋ₓSnX AlₓGa₁₋ₓAs, InₓGa₁₋ₓAs, IbₓGa₁₋ₓ, AlₓIn₁₋ₓSb, GaAsN, GaAsP, GaAsSb, AlGaN, AlGaP, InGaN, InAsSb, InGaSb.AlGaInP, AlGaAsP, InGaAsSb, InAsSbP, AlInAsP, AlInAsN, GaAsSbN, GaInNAsSb, GaInAsSbP, CdZnTe, HgCdTe, HgZnTe, HgZnSe, (Zn₁₋ₓCd)₃(P_{1-y}AsY)₂ and Cu(In, Ga)Se₂.

19. A method as in claim 6 which more specifically comprises the steps of:
a) selecting a semiconductor substrate having at least one polished side;
b) depositing or growing insulator on at least one polished surface thereof;
c) etching openings through insulator regions where material that forms rectifying junctions with both N and P-type semiconductor is to be present;
d) depositing or ion-implanting material that forms rectifying junctions with both N and P-type semiconductor;
e) annealing or otherwise causing the deposited material that forms rectifying junctions with both N and P-type semiconductor to form rectifying junctions with the semiconductor in the regions opened in step c);
f) removing unreacted material that forms rectifying junctions with both N and P-type semiconductor in all areas other than in the regions opened in step c);
g) opening areas in the insulator where ohmic contact to ends of channel regions are to be present;
h) depositing a material suitable for use as a gate over the entire substrate;
i) delineating the system such that said metal provides a gate over two channels in the semiconductor, said two channels projecting from the region of material that forms rectifying junctions with both N and P-type semiconductor, and ending at separate ohmic contact region; while also delineating ohmic contacts with regions of said material that forms rectifying junctions with both N and P-type semiconductor;
j) sintering said delineated system to form ohmic contacts at the ends of channels and with the regions of material that forms rectifying junctions with both N and P-type semiconductor.

20. A method as in claim 19, which further comprises at least one additional step selected from the group consisting of:
a′) conducting a semiconductor etch that forms substantially parallel adjacent pairs of FINS, each of which projects from the polished surface of said substrate, and the method is one of fabricating a compact FINFET CMOS system; and
b′) providing a relatively thin insulator over the entire substrate and then thinning it in the channel regions by removing selective etching, or by etching all insulator to the semiconductor in the eventual channel regions, and again growing or depositing a thinner layer of insulator appropriate for use as a crate insulator.
